(19) United States
(12) Patent Application Publication
(10) Pub. No.: US 2009/0214985 A1
(43) Pub. Date: Aug. 27, 2009

(54) METHOD FOR REDUCING SURFACE DEFECTS ON PATTERNED RESIST FEATURES

(75) Inventor: John M. KULP, Canyon Lake, TX (US)

Correspondence Address: Tokyo Electron U.S. Holdings, Inc., 4350 West Chandler Blvd., Suite 10/11, Chandler, AZ, 85226, US

(73) Assignee: TOKYO ELECTRON LIMITED, Tokyo (JP)

(21) Appl. No.: 12/038,031

(22) Filed: Feb. 27, 2008

(51) Int. Cl. G03F 7/26; H01L 21/306

(52) U.S. Cl. 430/322; 438/745; 257/E21.219

(57) ABSTRACT

A method is provided for post-processing lithographically patterned resists to reduce surface defects on a patterned resist feature. The method includes providing a substrate with a patterned resist feature containing surface defects with convex and concave regions, applying an acid solution to the patterned resist feature to form a surface acid layer on the patterned resist feature, heat-treating the patterned resist feature, where the heat-treating causes acid concentration in the convex regions and acid dispersion in the concave regions. The method further includes exposing the heat-treated patterned resist feature to a developing solution to preferentially remove resist material from the convex regions and form a trimmed patterned resist feature with reduced surface defects. According to one embodiment, the method further includes repeating the applying, heat-treating, and exposing at least once to further trim and reduce surface defects on the trimmed patterned resist feature.

### FIELD OF THE INVENTION

The invention is related to semiconductor processing, in particular, to methods for processing radiation sensitive material on a substrate (wafer).

### BACKGROUND OF THE INVENTION

Lithographic processes using radiation sensitive material (also referred to herein as “resist”) are widely used in the manufacture of semiconductor devices and other patterned structures. In track photolithographic processing used in the fabrication of semiconductor devices, the following sorts of processes may be performed in sequence: photoresist coating that coats a photoresist solution on a semiconductor wafer to form a resist film, heat processing to cure the coated resist film, exposure processing to expose a predetermined pattern on the photoresist film, heat processing to promote a chemical reaction within the photoresist film after exposure, developing processing to develop the exposed photoresist film, etc.

In a photolithographic process, the photoresist can be exposed to ultraviolet light according to a predetermined pattern and these exposed areas become soluble in an alkaline developer solution by activation of a photo acid generator (PAG) in the exposed areas. When the PAG is heated in a step called post exposure bake (PEB), the acid generated diffuses slightly and de-protects the adjacent binding dissolution inhibiter in the photoresist material. Next, the de-protected areas are rinsed away using the developer solution. The resulting patterned photoresist features (mask) define the areas of the substrate surface that are subject to further processing such as ion implantation into, or etch of, the substrate surface exposed in the openings of the mask.

The drive for increased density of features to improve the cost per function ratio of the microelectronic device being manufactured is driving the industry toward smaller and smaller features. The feature sizes currently being produced are well below 100 nm half pitch (half the distance between cells in a dynamic random access memory (RAM) memory chip), and the industry is being aggressively driven toward smaller feature sizes. As the drive toward smaller and smaller features continues, several new problems in the manufacture of these very small features are becoming visible. One problem is called line edge roughness (LER). In the smallest features being formed, the roughness, or non-linearity of an edge of a feature is a much higher percentage of the feature width, and therefore LER, and other surface defects, are currently projected to limit the usefulness of very small features in device production. Previous methods directed at improving LER have focused on preventing LER during resist patterning. What is needed are post-processing methods capable of correcting and reducing LER and other defects associated with very small patterned resist features.

### SUMMARY OF THE INVENTION

A method is provided for post-processing lithographically patterned resists to reduce surface defects on a patterned resist feature. The surface defects can include line edge roughness, and resist residue defects. Line edge roughness can include footing, T-topping, micro-bridging, standing wave vertical non-uniformity, or a combination thereof. In general, the post-processing method may be applied to a wide variety of surface defects containing resist residue.

The method includes providing a substrate with a patterned resist feature containing surface defects with convex and concave regions, applying an acid solution to the patterned resist feature to form a surface acid layer on the patterned resist feature, heat-treating the patterned resist feature, where the heat-treating causes acid concentration in the convex regions and acid dispersion in the concave regions, and exposing the heat-treated patterned resist feature to a developing solution to preferentially remove resist material from the convex regions and form a trimmed patterned resist feature with reduced surface defects. According to one embodiment, the method further includes repeating the applying, heat-treating, and exposing at least once to further trim and reduce surface defects on the trimmed patterned resist feature.

According to one embodiment of the invention, a method is provided for trimming a patterned resist feature characterized by a critical dimension (CD). The method includes providing a substrate with a patterned resist feature, the patterned resist feature being characterized by a critical dimension (CD); applying an acid solution to the patterned resist feature to form a surface acid layer on the patterned resist feature; and exposing the patterned resist feature to a developing solution to preferentially remove resist material from the surface acid layer. The method can further include, prior to the exposing, heat-treating the patterned resist feature containing the surface acid layer.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the principles of the invention.

FIGS. 1A and 1B are perspective and plan views showing an overall configuration of a coating/developing system that may be used in accordance with embodiments of the invention;

FIGS. 2A and 2B are perspective and plan views showing a coating unit of the coating/developing system shown in FIGS. 1A and 1B;

FIGS. 3A and 3B are perspective and plan views showing a developing unit of the coating/developing system shown in FIGS. 1A and 1B;

FIG. 3C is a perspective view of a nozzle assembly provided in the developing unit shown in FIGS. 3A and 3B;

FIG. 4 is a simplified process flow diagram for a method of patterning a resist coated wafer;

FIGS. 5A-5D are schematic cross-sectional views for the method of patterning a resist coated wafer shown in FIG. 4;

FIG. 6 is a cross-sectional view of a patterned resist feature that illustrates various surface defects that may be reduced or eliminated by post-processing according to embodiments of the invention;

FIG. 7 is a simplified flow diagram for a method of reducing surface defects of a patterned resist feature according to an embodiment of the invention;

FIGS. 8A-8D are schematic cross-sectional views for the method of reducing surface defects of the patterned resist feature shown in FIG. 7; and

FIG. 9 schematically shows concentrating effects of surface acid diffusion in convex regions and dispersion effects of surface acid diffusion in concave regions of surface defects on a patterned resist feature.

### DETAILED DESCRIPTION OF SEVERAL EMBODIMENTS

Embodiments of the invention provide a method for post-processing lithographically patterned resists to reduce surface defects in a patterned resist feature. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention.

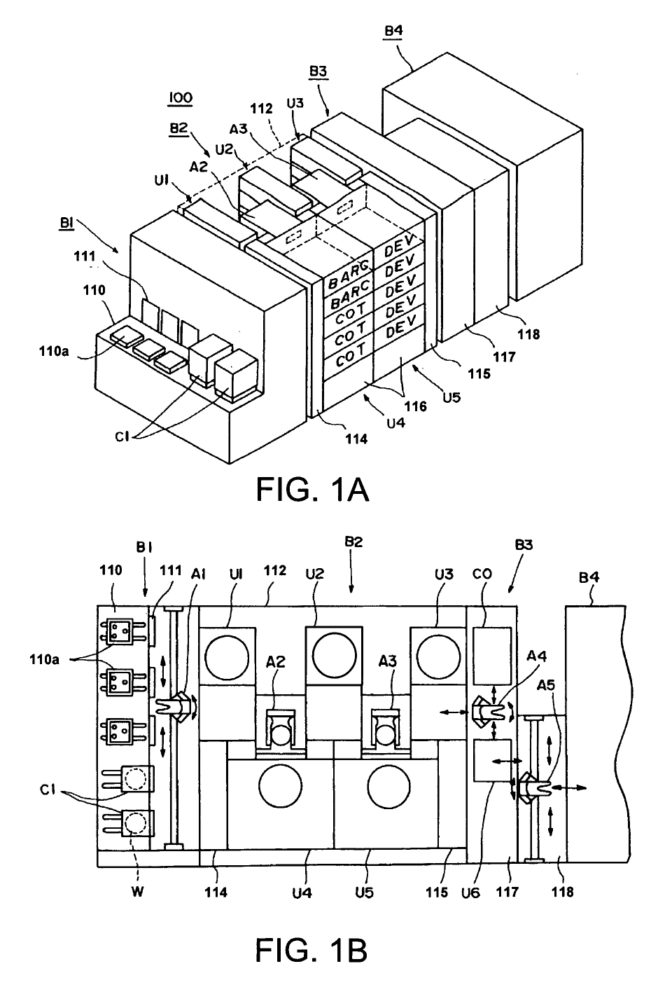

FIGS. 1A and 1B show perspective and plan views of a coating/developing system that may be used to form patterned features by photolithography and perform post-processing methods for reducing surface defects associated with the patterned features according to embodiments of the invention. Although a coating/developing system using ultraviolet (UV) light exposures is described herein, embodiments of the invention are not so limited, as a coating/developing system that uses charged particles such as electrons may also be used. For example, the coating/developing system can include an ACT 8, ACT 12, or Lithius Track System commercially available from Tokyo Electron Limited (TEL). The exemplary coating/developing processing system 100 in FIGS. 1A and 1B includes a carrier transport portion B1 for inserting and removing a sealed wafer transporter C1 containing substrates W. The transport portion B1 is provided with a transport station 110 having a transport portion 110a on which a plurality of wafer transporters C1 can be placed, an opening and closing portion 111 provided at a front wall surface as seen from transport station 110, and a transport means A1 (e.g., a robot) for removing a wafer W from wafer transporter C1 via opening and closing portion 111.

A processing portion B2, surrounded by a housing 112, is connected to the back of transport portion B1. In the processing portion B2, shelf units U1, U2 and U3, which are multiple stages of heating and cooling units, and transport means A2 and A3 for transferring wafers W between processing units including coating and developing units, are provided in an alternating arrangement. That is, shelf units U1, U2 and U3 and transport means A2 and A3 are linearly arranged when viewed from the transport portion B1. Once in the processing portion B2, a wafer W can easily move from shelf unit U1 to shelf unit U3. Temperature and humidity adjusting units 114 and 115 are provided that include a temperature adjusting apparatus for a processing liquid used in each unit, a duct for adjusting temperature and humidity, and the like.

As shown in FIG. 1A, liquid processing units U4 and U5 contain a storage portion 116 for supplying a solution such as a coating solution (resist solution) or a developing solution, resist coating units (COT), developing units (DEV), and units for forming a bottom anti-reflective coating (BARC). These units are vertically stacked to form a plurality of stages, e.g., five stages. The aforementioned shelf units U1, U2 and U3 each contain vertically stacked units for performing pre-processing and post-processing of wafers W processed in liquid processing units U4 and U5. The units for performing pre-processing and post-processing include heating units for heating (baking) wafer W, cooling units for cooling wafer W, and the like.

On the back side of shelf unit U3 in processing portion B2, an exposing portion B4 (e.g., for exposing a resist to UV light) is connected via an interface portion B3 containing a first transport chamber 117 and a second transport chamber 118, for example. As shown in FIG. 1B, inside interface portion B3, a shelf unit U6 and a buffer wafer transporter C0 are provided, in addition to transporting means A4 and A5 for transporting wafer W between processing portion B2 and exposing portion B4.

An exemplary flow of wafers W in the coating/developing system 100 includes, placing a wafer transporter C1 on transport station 110. Together with opening and closing portion 111, a lid of the wafer transporter C1 is removed and wafers W are removed from the wafer transporter C1 by transport means A1. Next, wafers W are pre-processed in one or more of shelf units U1-U3 with the aid of transport means A2 and A3. The pre-processing can include formation of a BARC on wafer W and cooling of a wafer W. Thereafter a wafer W is coated with a resist solution in a resist coating unit (COT).

Thereafter, a wafer W is heat-treated (baked) using a heating unit of one of the shelf units U1-U3, and then cooled. Next, the wafer W is placed in the interface portion B3 using a transport unit (not shown) of the interface portion B3. Once in the interface portion B3, the wafers W are transferred, for example using transport means A4, to shelf unit U6, and thereafter to exposing portion B4 using transporting means A5. The wafers W are exposed to pattern of ultraviolet light in exposing portion B4. After the exposure, the wafers W are transported back to the transport means A2 and developed at a developing unit (DEV). Thus, a patterned resist (resist mask) is formed on a wafer W. Thereafter, the wafer W containing the patterned resist may be post-processed according to embodiments of the invention to reduce surface defects on a patterned resist feature of a patterned resist. After the post-processing, the wafers W are returned to the wafer transporter C1 in the transport station 110 and removed from the coating/developing system 100.

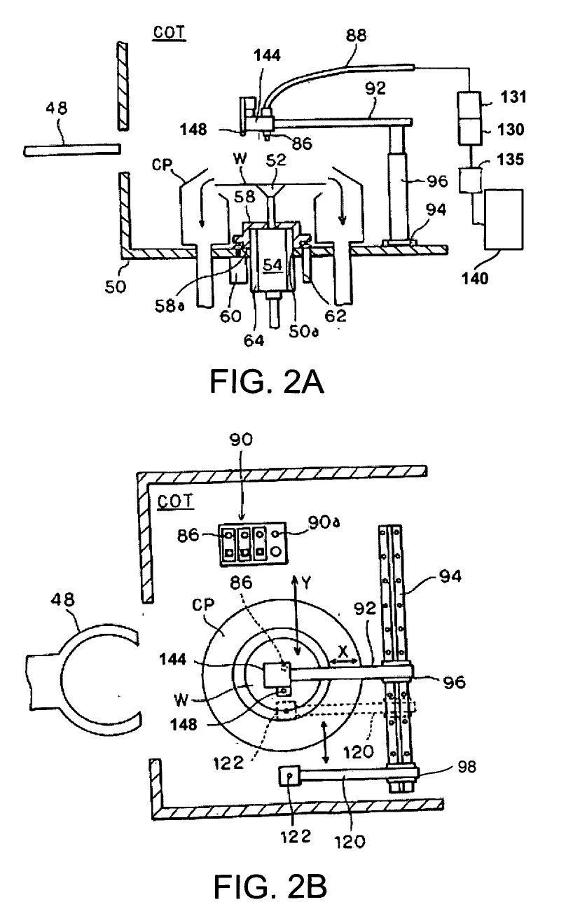

FIG. 2A is a sectional view and FIG. 2B is a plan view of a resist coating unit (COT) that may be used to coat a wafer W with a resist. As seen in FIGS. 2A and 2B, a ring-shaped cup CP is disposed at the center of the resist coating unit (COT), and a spin chuck 52 is disposed inside the cup CP. The spin chuck 52 is rotationally driven by a drive motor 54 while securely holding a wafer W by vacuum adherence. The drive motor 54 is disposed within an opening 50a provided in a unit bottom plate 50 that can be raised and lowered, and is linked together with a raising/lowering drive means 60 containing, for example, an air cylinder and a raising/lowering guide means 62 with a cap-shaped flange member 58, for example made of aluminum, therebetween.

On the side face of the drive motor 54, a cylindrical cooling jacket 64 made of, for example stainless steel, is attached, and the flange member 58 is attached in such a manner to cover the upper half of the cooling jacket 64.

When a resist is applied to the wafer W, a bottom end 58a of the flange member 58 contacts the unit bottom plate 50 in the vicinity of the periphery of the opening 50a, thereby keeping the inside of the unit airtight. When the wafer W is delivered between the spin chuck 52 and the wafer holding members 48 of a transport unit, the raising/lowering drive means 60 lifts the drive motor 54 or the spin chuck 52 upward, thereby the bottom end of the flange member 58 is raised away from the unit bottom plate 50.

A resist nozzle 86 for discharging a resist solution onto the front face of the wafer W is joined to a resist supply pipe 88 to which an air-operated valve 130 and a suck back valve 131 are joined. The resist nozzle 86 is removably attached to the tip portion of a resist nozzle scan arm 92 with a nozzle holder 144 therebetween. The resist nozzle scan arm 92 is attached to the top end portion of a vertical support member 96 which can horizontally move in one direction (Y-direction) on guide rails 94 laid on the unit bottom plate 50, so that it moves in the Y-direction integrally with the vertical support member 96 by a Y-direction drive mechanism (not shown).

The resist supply system in FIG. 2A includes a resist container 140 containing a batch of resist. The resist container 140 can supply resist to the resist supply pipe 88 via a batch change mechanism 135, as well as air-operated valve 130, suck back valve 131 and resist supply pipe 88. The resist nozzle scan arm 92 can move also in the X-direction orthogonal to the Y-direction for selectively attaching a resist nozzle 86 thereto at a resist nozzle standby section 90, and hence it also moves in the X-direction by an X-direction drive mechanism (not shown).

Further, a discharge port of the resist nozzle 86 is inserted into an aperture 90a of a solvent atmosphere chamber at the resist nozzle standby section 90 to be exposed to the atmosphere of the solvent therein, so that a resist solution at the nozzle tip does not solidify nor deteriorate. Moreover, a plurality of resists nozzles 86 are provided and these nozzles are properly used, for instance, corresponding to the type of resist solution.

Attached to the tip portion (the nozzle holder 144) of the resist nozzle scan arm 92 is a thinner nozzle 148 for discharging a solvent onto the front face of the wafer W in advance of the discharge of the resist solution onto the front face of the wafer W, for example, a thinner. The thinner nozzle 148 is joined to a thinner supply section with a solvent supply pipe (not shown) therebetween. The thinner nozzle 148 and the resist nozzle 86 are attached in such a manner that the respective discharge ports are positioned above a straight line along the Y-movement direction of the resist nozzle scan arm 92.

Still referring to FIGS. 2A and 2B, on the guide rails 94, in addition to the vertical support member 96 for supporting the resist nozzle scan arm 92, a vertical support member 98 is provided for supporting a side rinse nozzle scan arm 120 that is movable in the Y-direction. A rinse nozzle 122 for side rinse is attached to the tip portion of the side rinse nozzle scan arm 120. The Y-direction drive mechanism (not shown) translates or linearly moves the side rinse nozzle scan arm 120 and the rinse nozzle 122 between a side rinse nozzle standby position (a position shown by the solid line) which is set beside the cup CP and a rinse solution discharge position (a position shown by the dotted line) which is set direct above the peripheral portion of the wafer W mounted on the spin chuck 52.

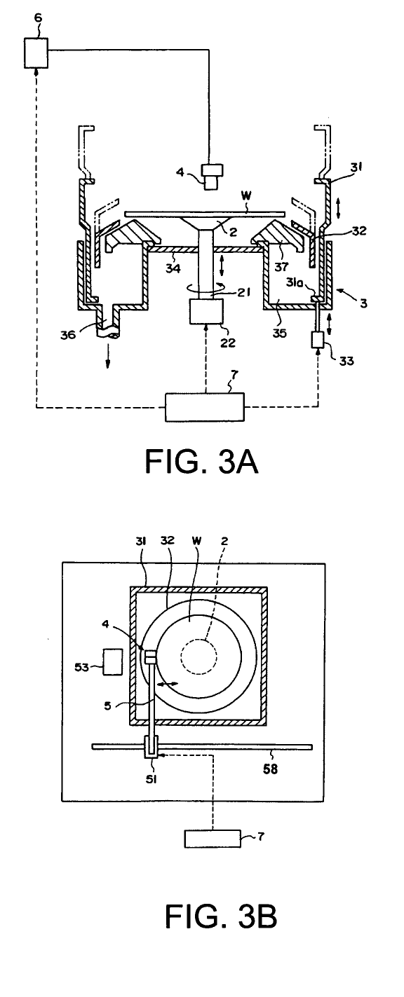

Next, an exemplary developing unit (DEV) is further described. FIGS. 3A and 3B are cross-sectional and plan views that schematically show a configuration of a developing unit (DEV). The developing unit (DEV) includes a spin chuck 2 that includes a substrate holding portion for holding a wafer W, in a horizontal attitude by holding the center of the back side of wafer W by suction. As shown in FIG. 3A, the spin chuck 2 is connected to a drive mechanism 22 (a rotary drive mechanism) via a rotational shaft 21, and configured to rotate and raise/lower with the wafer W held thereon. Typically, the wafer W is positioned on the rotational axis of spin chuck 2.

The cup body 3 has an opened top end that surrounds the wafer W on the spin chuck 2. The cup body 3 contains an outer cup 31 having a rectangular upper portion and a cylindrical lower portion, and a cylindrical inner cup 32 having an upper portion tilted inwardly. The outer cup 31 is raised/lowered using a raising/lowering portion 33 connected to the lower end of the outer cup 31. The inner cup 32 is configured to be raised when being pushed up by a step portion 31a formed on the inner circumferential surface of the lower end of outer cup 31.

As shown in FIG. 3A, a circular plate 34 is provided below the spin chuck 2. A liquid receiving portion 35 with a concave cross-section is provided externally to and along the entire circumference of the circular plate 34. A drain port 36 is formed in the bottom of liquid receiving portion 35. A developing solution, a rinse liquid, and other liquids that are discharged or spun off from wafer W are trapped within the liquid receiving portion 35, and subsequently discharged from the developing unit (DEV) through drain port 36. A ring member 37 having a substantially triangular cross-sectional shape is provided near the circular plate 34.

A nozzle assembly 4 capable of being raised/lowered and moving horizontally is positioned above the wafer W when the wafer W is held on the spin chuck 2 as shown in FIG. 3C. The nozzle assembly 4 contains a plurality of nozzles, including a developing solution nozzle 4a that is formed in a wedge shape and is tapered towards the lower end. A slit-like discharge port 41 is formed in the lower end surface of the developing solution nozzle 4a to discharge a developing solution in a form of a strip. Discharge port 41 is arranged such that its longitudinal direction is oriented from the periphery of the wafer W to the center of the wafer. The developing solution nozzle 4a is supplied with a prescribed flow rate (e.g., 600 ml/min) of a developing solution from a developing solution container (not shown) of supplying unit 6 shown in FIG. 3A. The supplying unit 6 is capable of adjusting the temperature of the developing solution to a prescribed temperature (e.g., 23° C.) and supply the nozzle 4a with the developing solution.

As shown in FIG. 3C, the nozzle assembly 4 further contains rinse nozzle 4d for discharging a small amount of rinse liquid, e.g., pure water, for rinsing a developing solution from the wafer W. Also, the rinse nozzle 4d may be utilized to discharge a wetting solution, e.g., pure water, to improve the wettability of the wafer W. Furthermore, the nozzle assembly 4 contains a gas nozzle 4b configured for exposing the wafer W to N₂ gas, and a surfactant nozzle 4e for discharging a surfactant to the wafer W. Still further, the nozzle 4 assembly contains an acid nozzle 4c for post-processing a patterned photoresist according to embodiments of the invention.

The solutions and N₂ gas are supplied to the respective nozzles of the nozzle assembly 4 from the supplying unit 6. The discharging angle of the nozzles are adjusted such that, when the nozzle assembly 4 moves and stops over the center of wafer W, the solutions and the N₂ gas can be exposed to the center of the wafer.

As shown in FIG. 3B, the nozzle assembly 4 is supported at one end of a nozzle arm 5 and a second end of the nozzle arm 5 is connected to a moving base 51 that contains an raising/lowering mechanism (not shown). The moving base 51 is configured to laterally move along a guide member 58. This allows the nozzle assembly 4 to move in a straight line from outside of wafer W to the center of the wafer W. FIG. 3B further shows a nozzle standby section 53 where the tip of each nozzle of the nozzle assembly 4 may be cleaned.

For example, when a resist-coated wafer W is exposed to a developing solution, the nozzle assembly 4 moves from the nozzle standby section 53 to the periphery of wafer W, and then the nozzle assembly 4 moves from the outside of wafer W to the center of the wafer W, while the developing solution is discharged in a form of a strip from discharge port 41 of the developing solution nozzle 4a. Also, at this moment, the wafer W rotates at a prescribed rotation rate (e.g., 1000 rpm) driven by driving mechanism 22, whereby wafer W is coated with the developing solution.

In FIG. 3B, a control unit 7 containing a computer that controls operations of the supplying unit 6, drive mechanism 22, raising/lowering portion 33, and moving base 51. Further, the control unit 7 controls the discharge of a developing solution, N₂ gas, a rinse liquid, a surfactant, and an acid solution to wafer W. The control unit 7 contains a storage unit for storing a processing program containing at least one processing recipe in the form of a software program that controls the moving operation of the nozzle assembly 4, including discharging operations of the nozzles 4a-4e and rotating operation of the wafer W. The software program is stored in the storage unit of control unit 7 in a storage medium such as hard disk, compact disk, magneto-optical disk, and a memory card, for example.

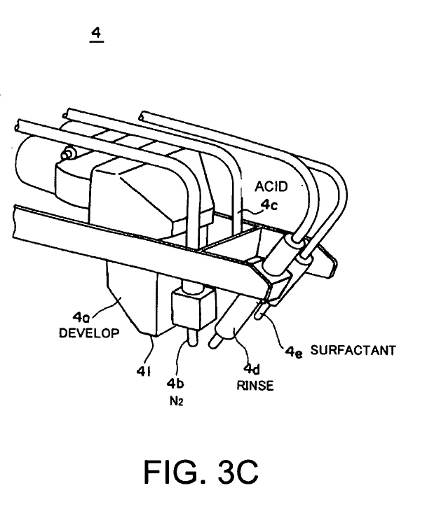

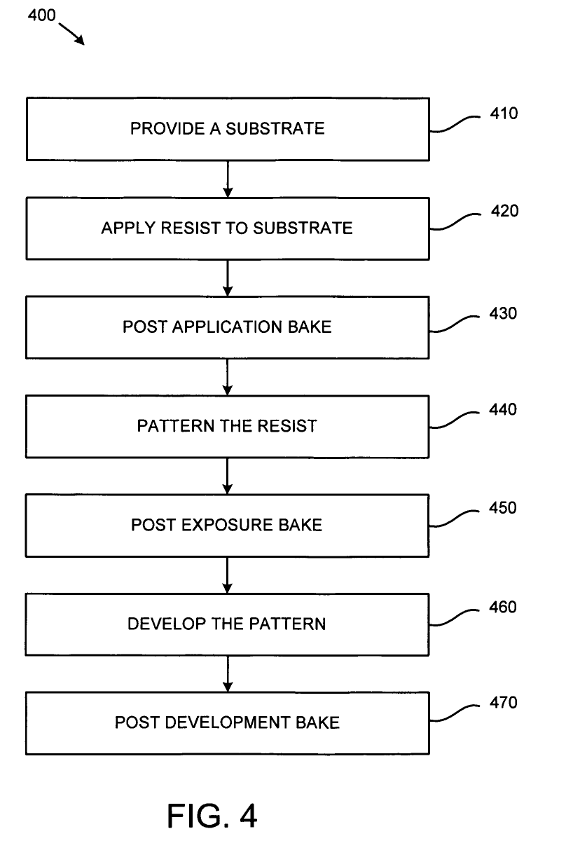

FIG. 4 is a simplified process flow diagram for a method of patterning a resist coated wafer, and FIGS. 5A-5D are schematic cross-sectional views for the method of patterning a resist coated wafer shown in FIG. 4. The patterning process produces a pattern that covers portions of a wafer W with a resist. For example, during a photolithography process, complex circuit patterns are imaged onto the photosensitive resist material by a lithography tool (e.g., exposing portion 4 in FIGS. 1A and 1B) to provide a physical barrier during further processing of the wafer to form semiconductor devices. During the further processing, the lithographic pattern can be transferred into the underlying wafer W or wafer layers by an etching process (e.g., a plasma etching process) that includes selective removal of wafer material not covered by resist.

The process 400 represents a typical lithography process to which embodiments of the invention can be applied. Referring also to FIGS. 1-3, starting in block 410, a wafer 500 is provided in coating/developing system 100 depicted in FIGS. 1-3.

In block 420, a resist 502 is applied to the wafer 500, as depicted in FIG. 5A. For example, the resist material can be applied by dispensing a liquid containing the resist material onto the wafer 500 while the wafer is mounted on a spin chuck 52 with a cup (CP), as depicted in FIGS. 2A and 2B. For example, the resist 502 can be a chemically amplified resist (CAR). A CAR can be characterized by an acid component, a quenched component, and an inhibitor quencher. In one example, an adhesion layer or a surfactant layer can be provided on the wafer surface before the resist material is applied.

CARs were developed to enhance the exposure process because of the low spectral energy of deep ultraviolet (DUV) radiation. A CAR contains one or more components that are insoluble in a developer solution. These components can comprise chemical protectors. A CAR can also contain a photoacid generator (PAG). During a radiation exposure step, the PAGs produce acid molecules for the patterning process. Desirably, the acid molecules remain inactive until a post exposure bake (PEB) is performed. The PEB drives a de-protection reaction forward in which the thermal energy causes the acid to react with the chemical protectors.

In block 430, a post application bake (PAB) can be performed in the coating/developing system 100 to cure the applied resist 502. In an alternate embodiment, a curing step is not required. In addition, a cooling step can be performed after the PAB. In a PAB heating unit, the resist 502 can be heated to temperatures at least higher than room temperature, and in a cooling unit, the resist, can be cooled to temperatures at or below room temperature.

In block 440, the resist 502 is patterned in a lithography tool using radiation 510, as depicted in FIG. 5B. The radiation 510 can include light radiation or charged particles such as electrons. The desired pattern can, for example, be created on the resist 502 using beams of high-energy electrons or arrays of laser beams and a mask that defines the size and shape of the pattern. For example, deep ultraviolet (DUV) can be used. DUV lithography is a key enabling technology that can be used to manufacture semiconductor devices with features of 0.25 microns (micron=10⁻⁶ m) or less. In other cases, extreme ultraviolet (EUV) sources can be used for critical dimensions below 0.05 microns. EUV lithography utilizes light with wavelengths in a range of about 5 nm to 50 nm, with about 13 nm being the most common.

In block 440, the resist 502 is exposed to the radiation 510 for a predetermined time period to achieve a desired exposure dose. Exposure dose refers to the amount of energy (per unit area) that the resist 502 is subjected to upon exposure by the lithography tool. For optical lithography, exposure dose is equal to the light intensity times the exposure time. In resist patterning, resolution is the smallest feature that can be printed (e.g., for a given process and processing system) with sufficient quality. It is common to use focus and exposure dose as process variables, so that resolution is defined as the smallest feature of a given type that can be printed with a specified depth of focus. The depth of focus of a feature is often defined as the range of focus that keeps the resist profile of a given feature within all specifications (e.g., linewidth, sidewall angle, resist loss) over a specified exposure range. The exposure in block 440 forms radiation exposed areas 506 and unexposed areas 504.

In block 450, a PEB process is performed in the coating/developing system 100 to drive the de-protection reaction forward. The de-protection reaction is acid driven and takes place in the areas exposed to the radiation 510. In addition, a cooling step can be performed after the PEB. In a PEB heating unit, the resist can be heated to temperatures at least higher than room temperature, and in a cooling unit, the resist can be cooled to temperatures at or below room temperature. FIG. 5C shows de-protected areas 508 and unexposed areas 504.

The PEB process plays an important role in the process 400. Heat-treating a resist can have many purposes that range from removing a solvent from the resist material to catalyzing the chemical amplification. In addition to the intended results, heat-treating can cause numerous problems. For example, the radiation sensitive component of the resist may decompose at temperatures typically used to remove the solvent, which is an extremely serious concern for a chemically amplified resist since the remaining solvent content has a strong impact on the diffusion and amplification rates. Also, heat-treating can affect the dissolution properties of the resist and thus have direct influence on the developed resist profile.

In block 460, the resist is developed in the coating/developing system 100 by selectively dissolving de-protected areas 508 of the resist. The developing process forms a patterned resist feature 512 with a dimension d₁ and an opening 514 in the resist. For example, an alkaline developing solution, such as a 2.3 wt % solution of tetramethyl ammonium hydroxide (TMAH), can be used. In addition, rinsing steps can also be performed.

For example, the patterned resist feature 512 can have an aspect ratio (height/width) greater than or equal to about 1:1, for example 2:1 3:1, 4:1, 5:1, 6:1, 12:1, 15:1, or higher. The patterned resist feature 512 can have a dimension d₁ of about 200 nm or less, for example 150 nm, 100 nm, 65 nm, 45 nm, 32 nm, 20 nm, or lower. However, embodiments of the invention are not limited to these aspect ratios or dimensions (feature widths), as other aspect ratios or via dimensions may be utilized.

In block 470, a post development bake (PDB) can be performed in the coating/developing processing system 100 to harden the resist pattern in preparation for subsequent pattern transfer into the underlying wafer or wafer layers. For example, the post development bake can improve the etch resistance of the patterned resist during plasma etching of the underlying wafer.

Following formation of a patterned resist, a critical dimension (CD) of the patterned resist may be inspected by an optical diffraction system at a plurality of test areas on the wafer to determine if it has been correctly manufactured. CD commonly refers to a dimension (e.g., width) of a feature formed in the resist, for example dimension d₁ of the patterned resist feature 512. Key requirements for the processing of wafers are tight CD control, tight profile control, and tight uniformity control—both within a wafer and wafer to wafer. For example, variations in CD measurements, profile measurements, and uniformity measurements are commonly caused by variations in temperature profile across a wafer and variations in thermal response from wafer to wafer.

Although not shown in the schematic cross-sectional view in FIG. 5D, the patterned resist feature 512 may contain surface defects such as line edge roughness (LER) and other defects associated with forming the patterned resist feature 512. As described in Background of the Invention, this is a severe problem encountered in the microelectronic device industry as it is being aggressively driven toward smaller feature sizes. Embodiments of the invention provide a post-processing method capable of correcting and reducing LER and other defects associated with very small patterned resist features.

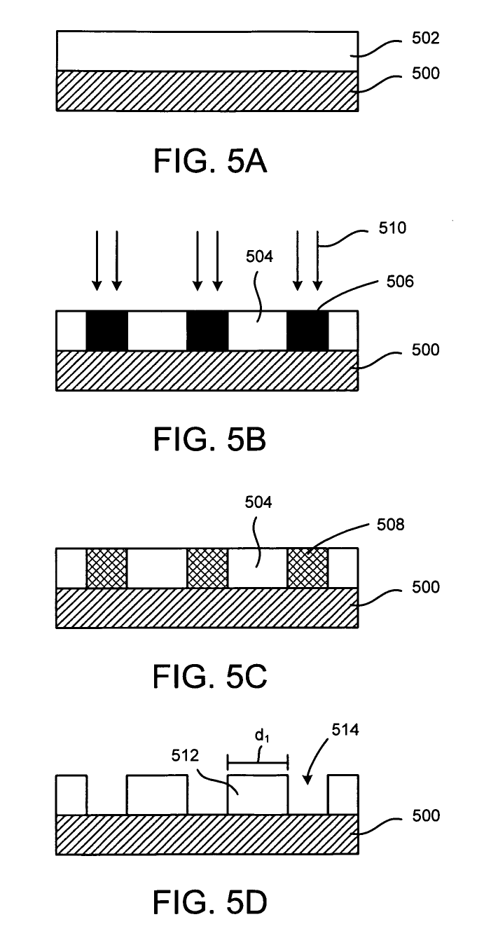

FIG. 6 is a cross-sectional view of a patterned resist feature 601 that illustrates various surface defects that may be reduced or eliminated by post-processing according to embodiments of the invention. These defects include, footing 602, which is an extension of the bottom of the patterned resist feature 601 into the space region (opening) between the patterned resist feature 601 and an adjacent patterned resist feature (not shown); T-topping 603, which is the extension of the top surface of the patterned resist feature 601 into the space region between an adjacent patterned resist feature (not shown); micro-bridging 604, where the extension of material from the patterned resist feature 601 contact and/or connect to a similar extensions from an adjacent patterned resist feature; standing wave vertical non-uniformity 605 caused by vertical variations in the exposed energy due to constructive and destructive interference between incident radiation and reflected radiation from the wafer surface 606; and resist residue defect 607. As seen in FIG. 6, surface defects on the patterned resist feature 601 contains a plurality of convex regions 608 and concave regions 609. Embodiments of the invention are well suited for preferentially removing resist material from the convex regions 608, thereby reducing surface defects on the patterned resist feature 601.

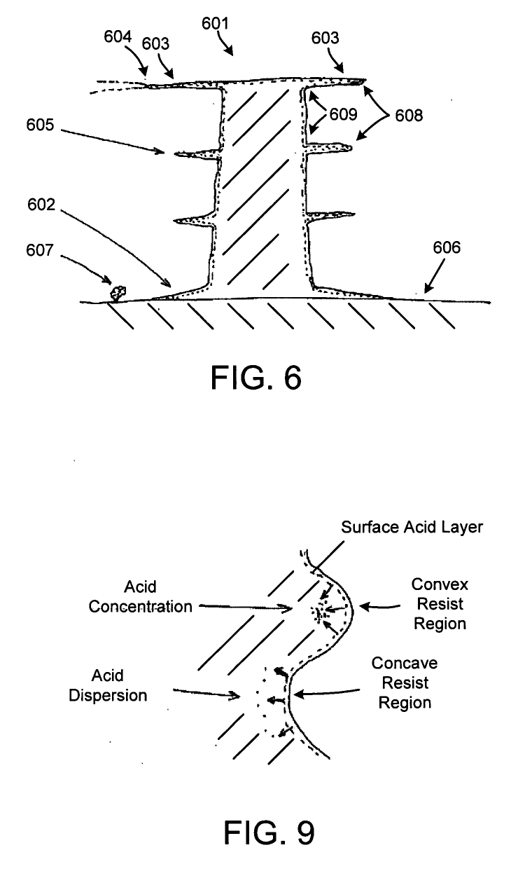

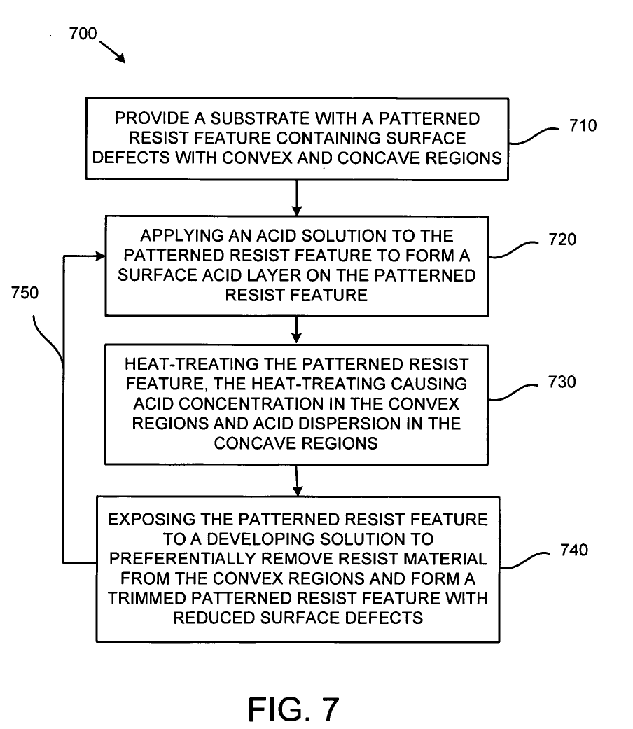

FIG. 7 is a simplified flow diagram for a method of reducing surface defects of a patterned resist feature according to an embodiment of the invention, and FIGS. 8A-8D are schematic cross-sectional views for the method of reducing surface defects of the patterned resist feature shown in FIG. 7. The patterned resist feature 804 can, for example, be patterned resist feature 512 in FIG. 5D formed by the method shown in the flow diagram of FIG. 4.

In block 710 of the process 700, a substrate 800 containing a patterned resist feature 804 with a dimension d₂ and an opening 802 is provided. Although not shown in FIG. 8A, the patterned resist feature 804 further contains surface defects, for example line edge roughness and other defects with convex and concave regions, as depicted in FIG. 6. According to one embodiment of the invention, the dimension d₂ of the patterned resist feature 804 may be selected to be greater than the desired final dimension following the post-processing, since the post-processing can result in reduction of the dimension d₂.

In block 720, an acid solution is applied to the patterned resist feature 804 to form a thin surface acid layer 806 on the patterned resist feature 804, as depicted in FIG. 8B. According to some embodiments of the invention, the acid solution can contain sulfur-containing acids but other acids may be used to form the thin surface layer. Examples of sulfur-containing acids include sulfuric acid, sulfonic acids and sulfonic acid derivatives such as salts and esters. Sulfonic acids are a class of organic acids with the general formula R—S(═O)₂—OH, where R is usually a hydrocarbon side chain. Examples of sulfonic acids include sulfonic acid (H—S(═O)₂—OH), methanesulfonic acid (CH₃S(═O)₂—OH), and p-toluenesulfonic acid (CH₃C₆H₄S(═O)₂—OH). Sulfonic acid salts include sulfonic acid chlorides with the general formula R—S(═O)₂—Cl. Examples include tosyl chloride, brosyl chloride, nosyl chloride, and mesyl chloride. The acid solution may, for example, be applied to the patterned resist feature 804 for a time period between 10 seconds and 600 seconds. Thereafter, the patterned resist feature 804 containing the surface acid layer 806 may be rinsed with de-ionized water to remove excess acid solution from the patterned resist feature 804 and other areas of the structure shown in FIG. 8B.

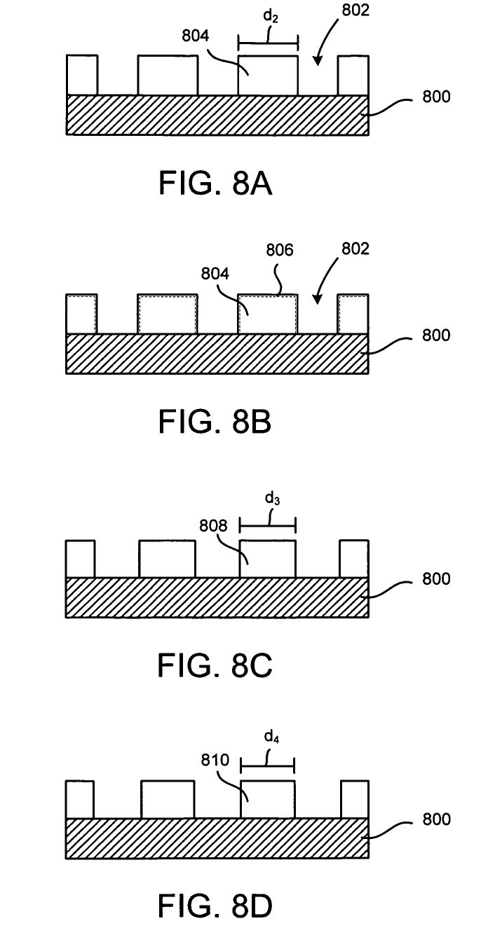

In block 730, the patterned resist feature is heat-treated. The heat-treating causes acid concentration in the convex regions and acid dispersion in the concave regions by acid diffusion. The heat-treating enables acid driven de-protection reaction where the concentration of the acid is high enough, in particular in the convex regions. FIG. 9 schematically shows concentrating effects of surface acid diffusion in convex regions and dispersion effects of surface acid diffusion in concave regions of surface defects on a patterned resist feature. As depicted in FIG. 9, acid will diffuse from the surface acid layer into the patterned resist feature in a direction approximately normal to the surface acid layer. This causes concentration of the acid in convex regions of the surface defect and acid dispersion in concave regions of the surface defect. De-protection reaction is enhanced in the convex regions due to the acid concentration effects in the convex regions.

In block 740, the heat-treated patterned resist feature is exposed to a developing solution that preferentially removes resist material from the convex regions and forms a trimmed patterned resist feature with reduced surface defects. A trimmed resist feature 808 is depicted in FIG. 8C. The trimmed patterned resist feature 808 has a dimension d₃ that is smaller than the width d₂ of the patterned resist feature 804 in FIG. 8A. The developing process preferentially dissolves and removes resist material in convex regions of surface defects on the patterned resist feature 804. Referring back to FIG. 6, the surface defects can include footing 602, T-topping 603, micro-bridging 604, vertical non-uniformity 605, and resist residue defect 607. As a result, line edge roughness is reduced and resist residue defects are removed. Although not shown in FIG. 8C, the developing process may further round sharp corners at the top of the patterned resist feature 804. If the patterned resist feature 804 is a line resist feature, the developing process may round ends of the line resist feature, and internal and external corners where the line resist feature abruptly changes direction on the substrate 800. These effects may require mask sets with mask dimension (bias) design for post-processing patterned resist features according to embodiments of the invention.

The processing in blocks 720-740 may be repeated any number of times as depicted by process flow arrow 750 to further reduce surface defects and further trim the trimmed patterned resist feature 808. FIG. 8D shows a further trimmed resist feature 810 with a dimension d₄ that is smaller than the dimension d₃ of the trimmed patterned resist feature 808.

According to embodiments of the invention, a post development bake (PDB) can be performed in the coating/developing system 100 following the post-processing described in FIGS. 7 and 8 to harden the trimmed patterned resist features 808 or 810 in preparation for subsequent pattern transfer into the underlying substrate or substrate layers.

According to one embodiment of the invention, a method is provided for trimming a patterned resist feature characterized by a critical dimension (CD). In a non-limiting example, the method may be utilized to trim the critical dimension d₂ depicted in FIG. 8A to form the trimmed critical dimension d₃ depicted in FIG. 8C. The method includes providing a substrate with a patterned resist feature, the patterned resist feature being characterized by a critical dimension (CD); applying an acid solution to the patterned resist feature to form a surface acid layer on the patterned resist feature; and exposing the patterned resist feature to a developing solution to preferentially remove resist material from the surface acid layer. The method can further include, prior to the exposing, heat-treating the patterned resist feature containing the surface acid layer.

A plurality of embodiments for post-processing lithographically patterned resists to reduce surface defects in a patterned resist feature and trimming a patterned resist feature have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. For example, the term “on” as used herein (including in the claims) does not require that a film “on” a substrate is directly on and in immediate contact with the substrate; there may be a second film or other structure between the film and the substrate.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method for reducing surface defects in a patterned resist feature, the method comprising:
providing a substrate with a patterned resist feature containing surface defects with convex and concave regions;
applying an acid solution to the patterned resist feature to form a surface acid layer on the patterned resist feature;
heat-treating the patterned resist feature, the heat-treating causing acid concentration in the convex regions and acid dispersion in the concave regions; and
exposing the heat-treated patterned resist feature to a developing solution to preferentially remove resist material from the convex regions and form a trimmed patterned resist feature with reduced surface defects.

2. The method of claim 1, wherein the surface defects comprise line edge roughness or resist residue defects.

3. The method of claim 2, wherein the line edge roughness comprises footing, T-topping, micro-bridging, standing wave vertical non-uniformity, or a combination thereof.

4. The method of claim 1, further comprising:
repeating the applying, heat-treating, and exposing at least once to further trim and reduce surface defects on the trimmed patterned resist feature.

5. The method of claim 1, wherein the acid solution comprises sulfuric acid, a sulfonic acid, or a sulfonic acid derivative.

6. The method of claim 1, wherein the developing solution comprises an alkaline solution.

7. The method of claim 1, the method further comprising:
prior to the heat-treating, rinsing excess acid solution from the patterned resist feature with de-ionized water.

8. The method of claim 1, wherein the patterned resist feature comprises a first dimension and the trimmed patterned resist feature comprises a trimmed dimension smaller than the first dimension.

9. The method of claim 8, wherein the substrate containing the patterned resist feature is formed by:
providing the substrate;
applying resist to the substrate;
performing a lithographic process on the resist to form the patterned resist feature with the first dimension.

10. The method of claim 1, wherein the resist is a photoresist.

11. The method of claim 10, wherein the photoresist is a chemically amplified photoresist (CAR) comprising a chemical protector and a photoacid generator (PAG).

12. A method for reducing surface defects in a patterned resist feature, the method comprising:
providing a substrate with a patterned resist feature having a first dimension and containing surface defects comprising line edge roughness or resist residue defects with convex and concave regions;
applying an acid solution to the patterned resist feature to form a surface acid layer on the patterned resist feature;
heat-treating the patterned resist feature, the heat-treating causing acid concentration in the convex regions and acid dispersion in the concave regions; and
exposing the heat-treated patterned resist feature to a developing solution to preferentially remove resist material from the convex regions and form a trimmed patterned resist feature with reduced surface defects, the trimmed patterned resist feature having a trimmed dimension smaller that the first dimension.

13. The method of claim 12, wherein the line edge roughness comprises footing, T-topping, micro-bridging, standing wave vertical non-uniformity, or a combination thereof.

14. The method of claim 12, further comprising:
repeating the applying, heat-treating, and exposing at least once to further trim and reduce surface defects on the trimmed patterned resist feature.

15. The method of claim 12, wherein the acid solution comprises sulfuric acid, a sulfonic acid, or a sulfonic acid derivative.

16. The method of claim 12, wherein the developing solution comprises an alkaline solution.

17. The method of claim 12, the method further comprising:
prior to the heat-treating, rinsing excess acid solution from the patterned resist feature with de-ionized water.

18. The method of claim 12, wherein the patterned resist feature comprises a first dimension and the trimmed patterned resist feature comprises a trimmed dimension smaller than the first dimension.

19. The method of claim 18, wherein the substrate containing the patterned resist feature is formed by:
providing the substrate;
applying resist to the substrate;
performing a lithographic process on the resist to form the patterned resist feature with the first dimension.

20. The method of claim 12, wherein the resist is a photoresist.

21. A method for trimming a patterned resist feature, the method comprising:
providing a substrate with a patterned resist feature, the patterned resist feature being characterized by a critical dimension (CD);
applying an acid solution to the patterned resist feature to form a surface acid layer on the patterned resist feature; and
exposing the patterned resist feature to a developing solution to preferentially remove resist material from the surface acid layer.

22. The method of claim 21, further comprising:
prior to the exposing, heat-treating the patterned resist feature containing the surface acid layer.
